(19) United States
(12) Patent Application Publication
(10) Pub. No.: US 2010/0173466 A1
(43) Pub. Date: Jul. 8, 2010

(54) METHOD FOR FABRICATING A SEMICONDUCTOR DEVICE

(76) Inventor: Ching-Hwa Tey, Singapore (SG)

Correspondence Address: NORTH AMERICA INTELLECTUAL PROPERTY CORPORATION, P.O. BOX 506, MERRIFIELD, VA, 22116, US

(21) Appl. No.: 12/350,239

(22) Filed: Jan. 8, 2009

(51) Int. Cl. H01L 21/336

(52) U.S. Cl. 438/300; 257/E21.409

(57) ABSTRACT

A method for fabricating a semiconductor device includes providing a substrate sequentially having a polysilicon layer and an insulating layer formed thereon; patterning the polysilicon layer and the insulating layer to form at least a gate structure on the substrate; forming lightly doped regions in the substrate respectively at two side of the gate structure; forming a spacer on a sidewall of the gate structure; forming barrier layers respectively on a top surface of the gate structure and surfaces of the substrate at two sides of the spacer, and forming a source/drain in the substrate respectively at two sides of the spacer.

### BACKGROUND OF THE INVENTION

1. Field of the Invention

The invention relates to a method for fabricating a semiconductor device, and more particularly, to a method capable of decreasing channeling effect.

2. Description of the Prior Art

Metal-Oxide-Semiconductor Field-Effect Transistors (MOSFETs) are typical devices used to carry out functions required in the integrated circuits. Please refer to FIG. 1, which is a cross-sectional drawing of a conventional MOSFET. Briefly speaking, steps of fabrication of a MOSFET include sequentially forming a dielectric layer 102 and an updoped polysilicon layer 104 on a substrate 100, patterning the abovementioned layers to form a gate structure 106. Then, with the gate structure 106 serving as a mask, an ion implantation is performed to form lightly doped drains (LDDs) 110 in the substrate 100 respectively at two sides of the gate structure 106. Then a spacer 112 is formed on a sidewall of the gate structure 106, and followed by forming a source/drain 120 in the substrate 100 respectively at two sides of the spacer 112 with the gate structure 106 and the spacer 112 serving as a mask.

Please still refer to FIG. 1. The polysilicon layer 104 is usually formed at an environmental temperature exemplarily of 620° C., thus the polysilicon layer 104 is formed with column structures within. As shown in FIG. 1, lines in the polysilicon layer 104 depict grain boundaries of the polysilicon. As mentioned above, because the gate structure 106 and the spacer 112 serve as a mask in the ion implantation for forming the source/drain 120, when the ions are implanted into the polysilicon layer 104 with a particular degree, those ions are easily introduced into the polysilicon layer 104 deeply along the grain boundaries of the column structures of the polysilicon layer 104. Therefore the implanted distance of the ions will exceed the predetermined depth in the polysilicon layer 104, which leads to a difficulty in the depth control of the ion implantation. The so-called channeling effect even makes the implanted ions penetrating not only the polysilicon layer 104 but also the dielectric layer 102. Therefore the quality of the dielectric layer 102 is deteriorated and adverse influences are exerted on stability and reliability of the dielectric layer 102. More serious, channeling effect causes threshold voltage (Vₜ) drift in MOSFET, it even makes the MOSFET unable to be turned off and leads to failure in the circuits.

Additionally, to prevent the depletion effect of the gate structure 106, which occurs between the polysilicon layer 104 and the gate dielectric layer 102 when the gate structure 106 is in an inversion, and decreases effect gate capacitance of the gate structure 106, the prior art had thinned down a height of the gate structure 106, which is the thickness of the polysilicon layer 104. Furthermore, as semiconductor technology improves, line width has been scaled down under 90 nm, the height of the gate structure 106, or the thickness of the polysilicon layer 104 is therefore decreased to prevent the depletion effect. However, it has been found that said approaches worsen the channeling effect.

In other prior art, the polysilicon layer 104 can be formed at an environmental temperature higher than 620° C., and the formed polysilicon layer 104 will possess bigger grains and clearer column structure, thus the channeling effect is also worsened. Since both of the abovementioned product requirement and the process parameters worsen the channeling effect, a method for fabricating semiconductor device that is able to decrease the channeling effect and the depletion effect without complicating the process control is in need.

### SUMMARY OF THE INVENTION

Therefore the present invention provides a method for fabricating a semiconductor device that is able to decrease both of the channeling effect and the depletion effect.

According to the claimed invention, a method for fabricating a semiconductor device is provided. The method includes steps of providing a substrate having a polysilicon layer and an insulating layer formed thereon; patterning the polysilicon layer and the insulating layer to form at least a gate structure on the substrate; sequentially forming light doped drains (LDDs) in the substrate respectively at two sides of the gate structure and a spacer on a sidewall of the gate structure; forming barrier layers respectively on a top surface of the gate structure and on surfaces of the substrate at two sides of the spacer; and forming a source/drain in the substrate under the barrier layers at two sides of the spacer.

According to the provided method, the barrier layers formed on the top surface of the gate structure obstruct the dopants from entering the polysilicon layer during the ion implantation used to form the source/drain. Thus the channeling effect, which makes the dopants be introduced deeply in the polysilicon layer along the grain boundaries even penetrate the polysilicon layer and the dielectric layer, is avoided. And therefore adverse influences on stability and reliability of the device and the caused Vₜ drift problem are alleviated. Furthermore, due to the formation of the barrier layers, rapid thermal processing (RTP) used to activate the dopants for forming the source/drain is performed without lowering its thermal budget. Therefore the depletion effect is also prevented.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional drawing of a conventional MOSFET.

FIGS. 2-5 are schematic drawings illustrating the method for fabricating a semiconductor device according to a first preferred embodiment of the present invention.

FIGS. 6-10 are schematic drawings illustrating the method for fabricating a semiconductor device according to a second preferred embodiment of the present invention.

FIG. 11 is a drawing illustrating a modification of the first preferred embodiment and the second preferred embodiment.

### DETAILED DESCRIPTION

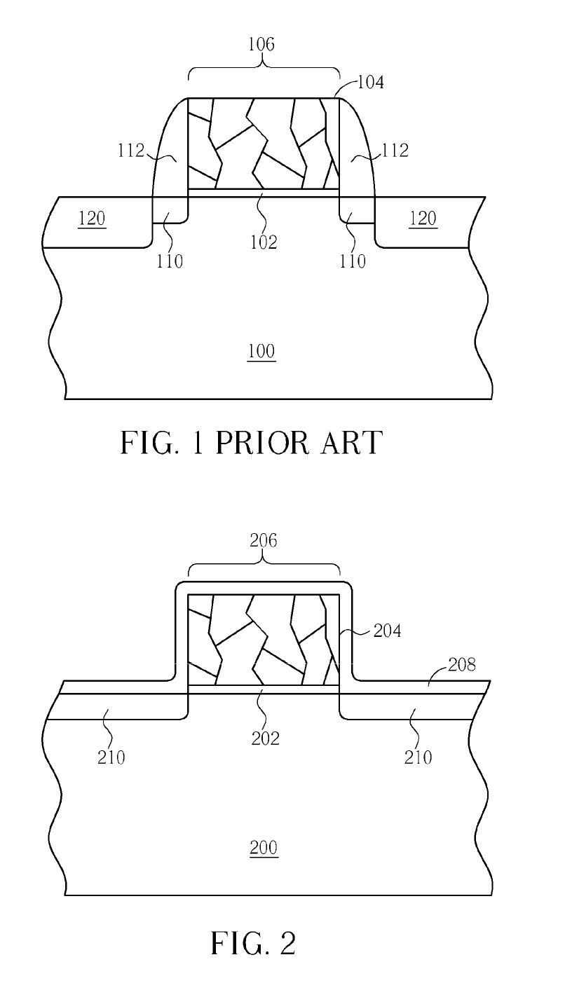

Please refer to FIGS. 2-5, which are schematic drawings illustrating the method for fabricating a semiconductor device according to a first preferred embodiment of the present invention. As shown in FIG. 2, a substrate 200 such as a silicon substrate or a silicon-on-insulator (SOI) substrate is provided. A dielectric layer 202 and a polysilicon layer 204 are sequentially formed on the substrate 200. Said dielectric layer 202 comprises insulating materials having oxygen, nitrogen, or oxygen/nitrogen components such as oxide or oxy-nitride, etc. The polysilicon layer 204 is formed by a chemical vapor deposition (CVD) method. Furthermore, the polysilicon layer 204 is formed at an environmental temperature higher than 600° C., such as 720° C., therefore the polysilicon layer 204 possesses column structure within. As shown in FIG. 2, lines in the polysilicon layer 204 depict the grain boundaries.

Please still refer to FIG. 2. The polysilicon layer 204 and the dielectric layer 202 are patterned to form at least a gate structure 206 on the substrate 200, and then, a liner 208 is formed on the substrate 200. The liner 208 comprises silicon oxide (SiO), and a thickness of the liner 208 is between 50 angstroms (Å) and 400 Å. However, it is well-known to those skilled in the art that the thickness and the material used in the liner 208 are not limited to this. Next, an ion implantation is performed to form doped regions (not shown) in the substrate 200 respectively at two sides of the gate structure 206, and followed by performing a RTP to activate dopants in the doped regions. Thus the lightly doped drains (LDDs) 210 are formed as shown in FIG. 2. Since said steps and the types of the implanted dopants, which are used depending on different types of the semiconductor device, are well known to those skilled in the art, details are omitted herein in the interest of brevity.

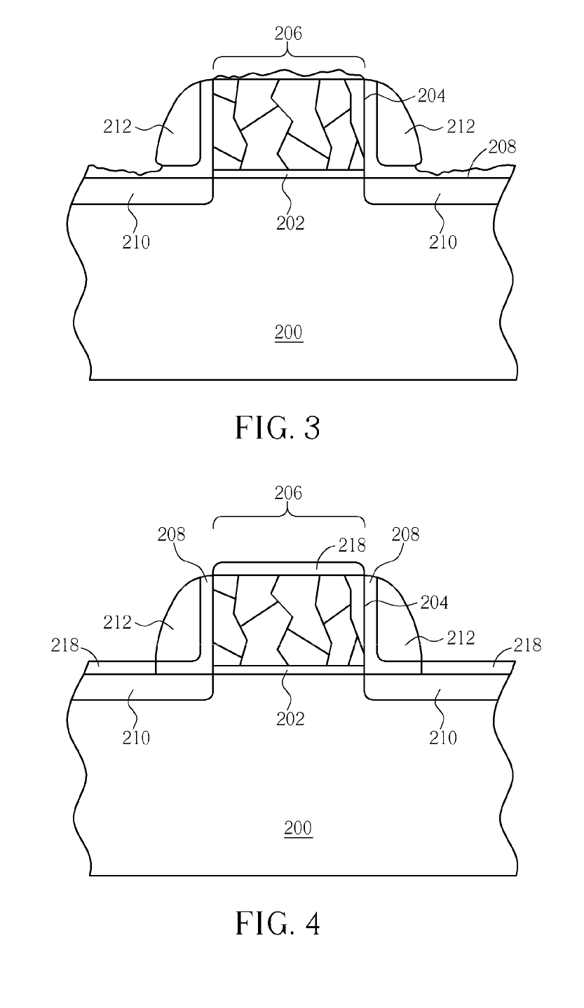

Please refer to FIG. 3. After forming the LDDs 210, a spacer 212 is formed on a sidewall of the gate structure 206. The spacer 212 is formed by forming a single or multiple layer on the substrate 200 first and then performing an etching back process with the liner 208 serving as the etch stop mask, thus the spacer 212 possessing a single or multiple lamination as shown in FIG. 3 is obtained. The single or multiple layer comprises silicon oxide (SiO), silicon nitride (SiN), silicon oxy-nitride (SiON), or other dielectric materials. Those skilled in the art would easily realize that the provided spacer 212 can be a combination of other shapes, different materials and laminations without being limited to the first preferred embodiment.

Please refer to FIG. 4. It is often found that, after the etching back process, remnant liner 208 is left on top surface of the structure 208 and on the substrate 200. Therefore a dilute HF (DHF) cleaning step is performed after forming the spacer 212. During the DHF cleaning step, the remnant liner 208, undesired particles, or native oxide on the top surface of the gate structure 208 and the substrate 200 are all removed by the DHF.

Please still refer to FIG. 4. After the DHF cleaning process, barrier layers 218 are formed on the top surface of the gate structure 206 and on the surfaces of the substrate 202 at two sides of the spacer 212. The barrier layer 218 is formed by a CVD method, a plasma ash method, or a H₂O₂ dipping method, and comprises SiO or SiON. In the first preferred embodiment, a thickness of the barrier layer 218 is between 8 Å and 18 Å, and a preferable thickness of the barrier layer 218 is 13 Å. The plasma ash method is performed at a temperature between 180° C. and 270° C., preferably at 250° C. A process duration of the plasma ash method is between 90 seconds and 150 seconds, preferably 90 seconds. Additionally, in a modification of the first preferred embodiment, the plasma ash method further comprises introduction of Nitrogen, thus barrier layers 218 comprising SiON are obtained.

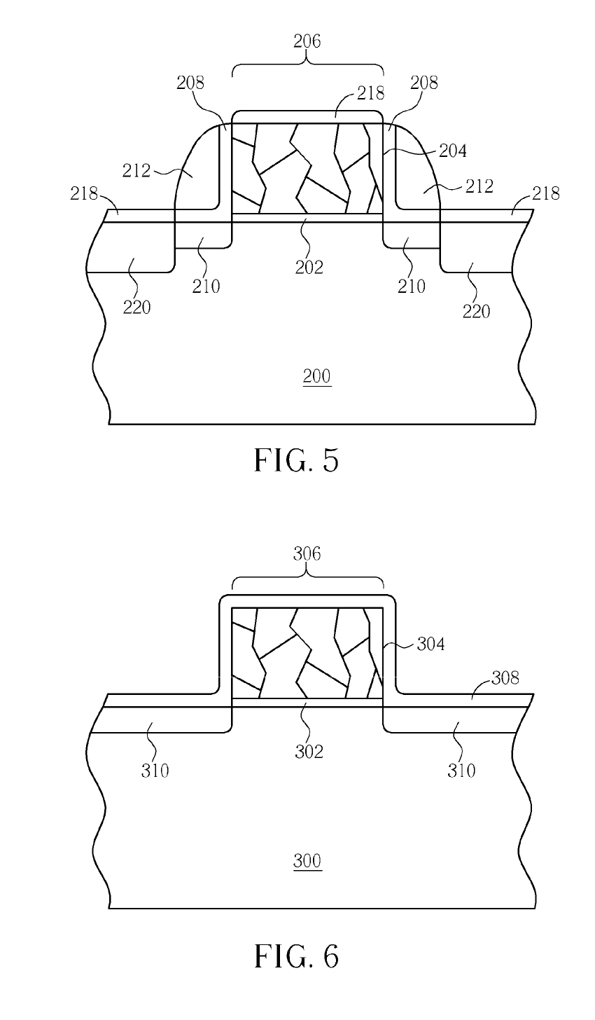

Please refer to FIG. 5. An ion implantation is then performed to form doped regions (not shown) in the substrate 218 respectively at two sides of the spacer 212, and followed by performing a RTP to activate dopants in the doped regions. Thus source/drain 220 is obtained as shown in FIG. 5.

In the first preferred embodiment, the barrier layer 218 formed on the top surface of the gate structure 206 obstruct the dopants from entering the polysilicon layer 204 during the ion implantation for forming the source/drain 220, thus the channeling effect, which makes the dopants be introduced deeply in the polysilicon layer 204 along the grain boundaries even penetrate the polysilicon layer 204 and the dielectric layer 202, is avoided. And therefore adverse influences on stability and reliability of the device and the caused Vₜ drift problem are alleviated. Furthermore, due to the formation of the barrier layers 218, RTP used to activate the dopants for forming the source/drain 220 is performed without lowering its thermal budget. Therefore the depletion effect is also prevented.

FIGS. 6-10, which are schematic drawings illustrating the method for fabricating a semiconductor device according to a second preferred embodiment of the present invention. As shown in FIG. 6. A substrate 300 such as a silicon substrate or a SOI substrate is provided. And as mentioned above, a dielectric layer 302 comprising insulating materials having oxygen, nitrogen, or oxygen/nitrogen components such as oxide or oxy-nitride, etc, and a polysilicon layer 304 formed by a CVD method are sequentially formed on the substrate 300. The polysilicon layer 304 is formed at an environmental temperature higher than 600° C., such as 720° C., thus column structures are obtained within. As shown in FIG. 6, lines in the polysilicon layer 304 exemplarily depict grain boundaries. Next, the polysilicon layer 304 and the dielectric layer 302 are patterned to form at least a gate structure 306 on the substrate 300.

Please still refer to FIG. 6. A liner 308 is formed on the substrate 300. The liner 308 comprises SiO, and a thickness of the liner 308 is between 50 Å and 400 Å. However, it is well-known to those skilled in the art that the thickness and the material used in the liner 308 are not limited to this. Then, an ion implantation is performed to form doped regions (not shown) in the substrate 300 respectively at two sides of the gate structure 306, followed by performing a RTP to activate dopants in the doped regions, thus LDDs 310 are obtained as shown in FIG. 6. Since said steps and types of the dopants, which are used depending on different type of the semiconductor device, are well known to those skilled in the art, details are omitted herein in the interest of brevity.

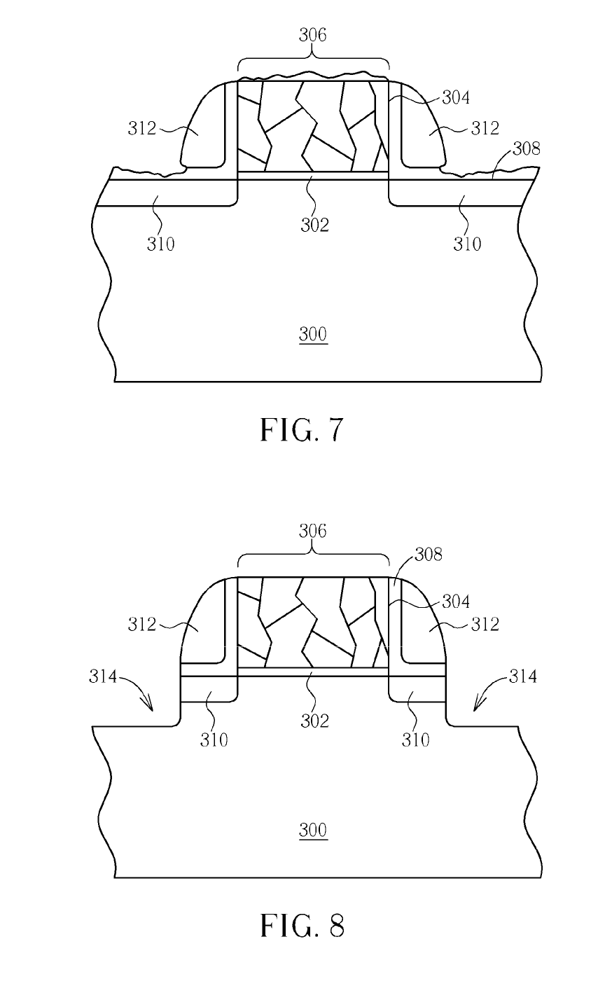

Please refer to FIG. 7. After forming the LDDs 310, a spacer 312 is formed on a sidewall of the gate structure 306. The spacer 312 is formed by forming a single or multiple layer on the substrate 300 and then performing an etching back process with the liner 308 serving as the etch stop mask, thus the spacer 312 possesses a single or multiple lamination as shown in FIG. 7 is obtained. The single or multiple layer comprises SiO, SiN, SiON, or other dielectric materials. Those skilled in the art would easily realize that the provided spacer 312 can be a combination of other shapes, different materials and laminations but not limited to the second preferred embodiment.

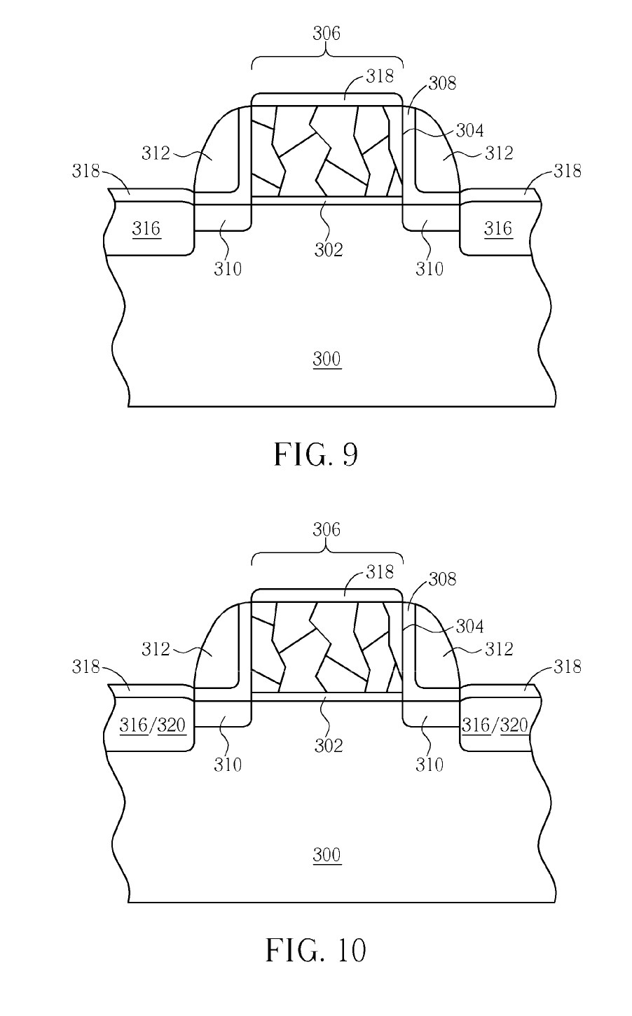

Please refer to FIGS. 8-9. Next, an etching process is performed to form recesses 314 in the substrate 300 respectively at two sides of the spacer 312. After forming the recesses 314, a pre-clean process is performed, and then a baking process is performed by using a temperature between 700° C. and 950° C. to remove the remaining oxides from the surface of the recesses 314 and repair the surface roughness of the recesses 314. Then, a selective epitaxial growth (SEG) process is performed to form epitaxial layers 316 respectively in the recesses 314. The epitaxial layers 316 comprise SiGe or SiC, depending on type requirement to the semiconductor device. In the second preferred embodiment, the SEG technique is utilized to form the epitaxial layers 316, which possess larger lattice constant than the substrate 300. Such characteristic is employed to cause alteration to the band structure of the silicon in the channel region of the substrate 300. Thus carrier mobility and performance of the semiconductor device are improved.

Please refer to FIG. 9. After the epitaxial layers 316 are formed by the SEG process, a DHF cleaning step is performed. During the DHF cleaning step, the remnant liner 308, undesired particles, or native oxide on the top surface of the gate structure 308 and the substrate 300 are all removed by the DHF. Then, barrier layers 318 are respectively formed on a top surface of the gate structure 306 and surfaces of the epitaxial layers 310. As mentioned above, the barrier layers 318 are formed by a CVD method, a plasma ash method, or a H₂O₂ dipping method and comprises SiO or SiON. In the second preferred embodiment, a thickness of the barrier layer 318 is between 8 Å and 18 Å, and a preferable thickness of the barrier layer 318 is 13 Å. The conditional parameter of the plasma ash method is identical to the first preferred embodiment while the preferred environmental temperature is at 250° C. and the preferred process duration is 90 seconds in the second preferred embodiment. In a modification of the second preferred embodiment, the plasma ash method further comprises introduction of Nitrogen, thus barrier layers 318 comprising SiON are obtained.

Please refer to FIG. 10. An ion implantation is then performed to form doped regions (not shown) in the epitaxial layer 316, and followed by performing a RTP to activate dopants in the doped regions. Thus source/drain 320 is obtained as shown in FIG. 10.

In the second preferred embodiment, the barrier layer 318 formed on the top surface of the gate structure 306 obstruct the dopants from entering the polysilicon layer 304 during the ion implantation for forming the source/drain 320, thus the channeling effect, which makes the dopants be introduced deeply in the polysilicon layer 304 along the grain boundaries even penetrate the polysilicon layer 304 and the dielectric layer 302, is avoided. And therefore adverse influences on stability and reliability of the device and the caused Vₜ drift problem are alleviated. Furthermore, due to the formation of the barrier layer 318, RTP used to activate the dopants for forming the source/drain 320 is performed without lowering its thermal budget. Therefore the depletion effect is also prevented.

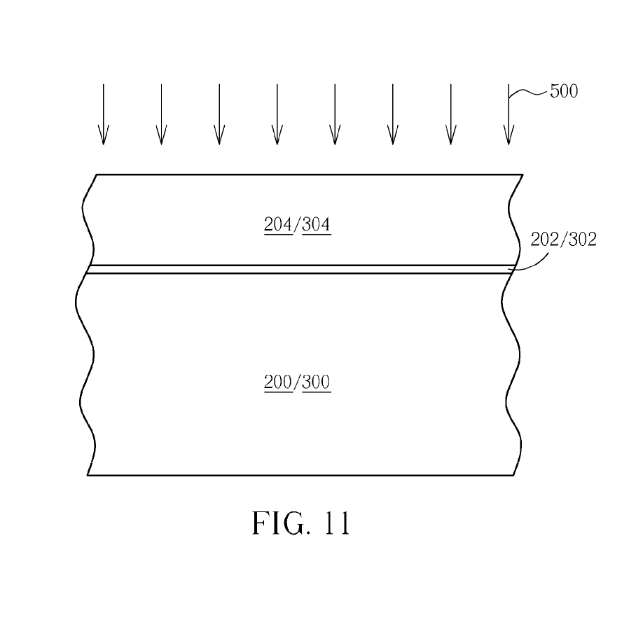

Furthermore, please refer to FIG. 11, which is a drawing illustrating a modification of the first preferred embodiment and the second preferred embodiment. In the first preferred embodiment and the second preferred embodiment, another ion implantation 500 is performed after forming the polysilicon layer 204/304. The ion implantation comprises Germanium (Ge), Phosphorous (P), Oxygen (O), or Nitrogen (N). Those introduced ions strike the silicon crystalline in the column structures in the polysilicon layer 204/304, thus a rumpled amorphous structure is formed in the polysilicon layer 204/304. Accordingly, the channeling effect is alleviated.

As mentioned above, according to the provided method, the barrier layer formed on the top surface of the gate structure obstruct the dopants from entering the polysilicon layer during the ion implantation for forming the source/drain, thus the channeling effect, which makes the dopants be introduced deeply in the polysilicon layer along the grain boundaries even penetrate the polysilicon layer and the dielectric layer, is avoided. And therefore adverse influences on stability and reliability of the device and the caused Vₜ drift problem are alleviated. Furthermore, due to the formation of the barrier layer, rapid thermal processing (RTP) used to activate the dopants for forming the source/drain is performed without lowering its thermal budget. Therefore the depletion effect is also prevented.

Those skilled in the art will readily observe that numerous modifications and alterations of the device and method may be made while retaining the teachings of the invention.

What is claimed is:

1. A method for fabricating a semiconductor device comprising steps of:
providing a substrate having a polysilicon layer and an insulating layer formed thereon;
patterning the polysilicon layer and the insulating layer to form at least a gate structure on the substrate;
sequentially forming light doped drains (LDDs) in the substrate at two sides of the gate structure and a spacer on a sidewall of the gate structure respectively;
forming barrier layers respectively on a top surface of the gate structure and on surfaces of the substrate at two sides of the spacer; and
forming a source/drain in the substrate under the barrier layers at two sides of the spacer.

2. The method of claim 1 further comprising a step of performing an ion implantation after forming the polysilicon layer.

3. The method of claim 2, wherein the ion implantation utilizes Germanium (Ge), Phosphorous (P), Oxygen (O), or Nitrogen (N).

4. The method of claim 1 further comprising a dilute HF (DHF) cleaning step performed after forming the spacer.

5. The method of claim 1, wherein the barrier layers are formed by a chemical vapor deposition (CVD) method, a plasma ash method, or a H₂O₂ dipping method.

6. The method of claim 5, wherein the plasma ash method further comprises introduction of Nitrogen.

7. The method of claim 5, wherein the barrier layers comprise silicon oxide or silicon oxy-nitride.

8. The method of claim 1 further comprising a step of performing a selective epitaxial growth (SEG) process after forming the spacer, and the SEG process further comprises:
forming a recess in the substrate respectively at two sides of the spacer; and
forming epitaxial layers respectively in the recesses.

9. The method of claim 8, wherein the epitaxial layers comprise SiGe or SiC.

10. The method of claim 8 further comprises a DHF cleaning step performed after the SEG process.

11. The method of claim 8, wherein the barrier layers are respectively formed on the top surface of the gate structure and surfaces of the epitaxial layers.

12. The method of claim 1, wherein a thickness of the barrier layer is between 8 and 18 angstroms.
